(19) United States
(12) Patent Application Publication
(10) Pub. No.: US 2017/0290202 A1
(43) Pub. Date: Oct. 5, 2017

(54) MULTIPLE SERVER ARCHITECTURE, SERVER MODULE, AND COOLER MODULE SYSTEMS AND ARCHITECTURE

(71) Applicant: Tango Tech, Inc., San Diego, CA (US)

(72) Inventor: Bhavesh Shah, San Diego, CA (US)

(21) Appl. No.: 15/624,633

(22) Filed: Jun. 15, 2017

Related U.S. Application Data
(63) Continuation-in-part of application No. 14/588,987, filed on Jan. 5, 2015.
(60) Provisional application No. 62/350,192, filed on Jun. 15, 2016.
(60) Provisional application No. 61/924,858, filed on Jan. 8, 2014.

(51) Int. Cl. H05K 7/20; G06F 13/40; H05K 7/14; G06F 1/20

(52) U.S. Cl. CPC H05K 7/20781; G06F 1/206; G06F 13/4081; H05K 7/1492; H05K 7/2039

(57) ABSTRACT

Embodiments of multiple server architecture with server modules and cooler modules wherein the server modules may be slide from the server architecture back to front to enable servers to be seated or removed transversely from a server module relative to server architecture front. Other embodiments may be described and claimed.

### CROSS REFERENCE TO RELATED APPLICATION

This application is a provisional conversion of U.S. Patent Application No. 62/350,192, Attorney Docket Number TG002US, filed Jun. 15, 2016 and entitled “Method and Apparatus for fanless servers” and a continuation-in-part of U.S. patent application Ser. No. 14/588,987, Attorney Docket Number TG001US1, filed Jan. 1, 2015 and entitled “Computer and Docking Station and Method”, which is a provisional conversion of U.S. Patent Application No. 61/924,858, Attorney Docket Number TG001US, filed Jan. 1, 2014 and entitled “Computer and Docking Station and Method”, each of which is incorporated by reference in their entirety.

### TECHNICAL FIELD

Various embodiments described herein relate to server racks and their various components.

### BACKGROUND INFORMATION

It may be desirable to provide a multiple server architecture or racks that reduce size, maintenance, reliability, and cooling costs, the present invention provides such multiple server architecture or racks.

### BRIEF DESCRIPTION OF THE DRAWINGS

FIG. 1A is a simplified front diagram of a multiple server architecture with server modules, spacer modules, and cooler modules according to various embodiments.

FIG. 1B is a simplified side diagram of a multiple server architecture with server modules, spacer modules, and cooler modules according to various embodiments.

FIG. 1C is a simplified front diagram of a multiple server architecture with server modules, spacer modules, and cooler modules with a server partially seated in a server module according to various embodiments.

FIG. 1D is a simplified side diagram of a multiple server architecture with server modules, spacer modules, and cooler modules with a server module partially slid forward to enable access to servers according to various embodiments.

FIG. 1E is a simplified enlarged side diagram of area AA of multiple server architecture shown in FIG. 1D according to various embodiments.

FIG. 1F is a simplified side diagram of a multiple server architecture with server modules, spacer modules, and cooler modules with server modules removed according to various embodiments.

FIG. 1G is an isometric image of a multiple server architecture with server modules, spacer modules, and cooler modules with a server module partially slid forward to enable access to servers according to various embodiments.

FIG. 1H is a partial block diagram of a multiple server architecture with server modules, spacer modules, and cooler modules according to various embodiments.

FIG. 2 is a simplified front diagram of a configuration of a plurality of multiple server architectures with server modules, spacer modules, and cooler modules according to various embodiments.

FIG. 3A is a partial block diagram of a server according to various embodiments.

FIG. 3B is an isometric image of a server according to various embodiments held by a User's hand.

FIG. 4A is a partial block diagram of a server module according to various embodiments.

FIG. 4B is an enlarged diagram of area BB shown in FIG. 4A according to various embodiments.

FIG. 4C is an isometric image of a server module according to various embodiments.

FIG. 5A is a simplified front diagram of another multiple server architecture with server modules and cooler modules according to various embodiments.

FIG. 5B is a simplified side diagram of a multiple server architecture shown in FIG. 5A with server modules and cooler modules with a server module partially slid forward to enable access to servers according to various embodiments.

FIG. 5C is an isometric image of a multiple server architecture shown in FIG. 5A with server modules and cooler modules with a server module partially slid forward to enable access to servers according to various embodiments.

### DETAILED DESCRIPTION

Computer data centers may include servers organized in server racks, which in turn, are organized in multiple rows of racks. A server may produce substantial heat, upward s to 500 watts when active and may have multiple fans arranged so it main processor or CPU, memory, and other parts may be cooled to remain operational. Additionally, a server may have at least one power supply which is cooled through one or more fans. Such cooling designs employ air circulation and may require a bulky heatsink inside the server.

Such a cooling design may also need a large amount of empty space inside the server and around the server when operation to enable sufficient air passage. In practice an air-cooled server organized in the server rack generally intakes cooler air from its front side and expels heated air from its back side. Such a configuration may create several problems. The configuration may require or need so called “cold aisles” and “hot aisles” for relatively isolated air flows. It may be important not to mix the cold and hot air flows to maximum cooling efficiency. Server racks may need to include space to provide hot and cold aisles, wasting limited data center space.

The heat produced by hundreds or even thousands of computers in a computer data center may be massive, hundreds of kilowatts or megawatts of heat generation. Dissipating such heat loads may require large scale equipment including a CRAH (Computer Room Air Handler). A CRAH may cools the air blown by large fans through a maze of concealed copper tubes running chilled water. In a smaller facility, a CRAC (Computer Room Air Conditioner) is used in place of CRAH. Nonetheless, air cooled server racks and servers may require additional space for equipment, air channels and additional costs including building, engineering, planning, and operational costs.

CRAH systems may include large fans that can consume up to 60% of the total cooling energy costs just to move air through the servers and rack aisles. In addition, air used to cool the servers may be circulated in the data center building. The data center cooling air may become warmed due to environment outside the building possibly increasing energy costs. All the above drawbacks, which ultimately may result in a high energy bill, may be reduced when the servers, server racks or architecture are cooled with cold water directly, instead of indirectly, i.e. using cold water to cool air. Some systems employ a water cooled heatsink mechanism where a water circuit is placed within the heatsink to cool a CPU on the board, e.g. in some enthusiast computers.

Such a water-cooled-heat sink configuration (coupled to a computer CPU) may not be easily implemented in high-availability, mission critical server racks. Such a system may need the water carrying pipes to run inside server of a server rack, which may introduce potential electrical short circuits. Further, water-cooled-heat sink configuration (coupled to a computer CPU) only cools the computer CPU. Other cooling mechanisms may be required to cool the rest of a server's electronics including via air circulation. Further in some water-cooled-heat sink configurations (coupled to a computer CPU), heated water may be cooled via a bulky air-cooled, fan driven heat exchanger where the heat exchanger may be situated at the back of the PC, potentially nullifying any possible advantages gained. In addition, the above mechanism requires water (or other liquid) to be delivered inside the system which needs liquid carrying pipes and couplings and may need to be connected or disconnected when the system needs to be connected or disconnected from use. In addition, such a mechanism may also create the hazard of water leakage.

It is noted in this description that any directional prepositions such as up, upwardly, down, downwardly, front, back, top, upper, bottom, lower, left, right, and other such terms refer to the device or depictions as such may be oriented are describing such as it appears in the drawings and are used for convenience only. Such terms of direction and location are not intended to be limiting or to imply that the modules or methods herein has to be used or positioned with graphics in any particular orientation. Further computer and network terms such as network, computer, portable, device, and other terms are for descriptive purposes only, and should not be considered limiting, due to the wide variance in the art as to such terms depending on which practitioner is employing them. The system herein should be considered to include any and all manner of software, firmware, operating systems, executable programs, files and file formats, databases, computer languages and the like, as would occur to one skilled in the art in any manner as they would be described.

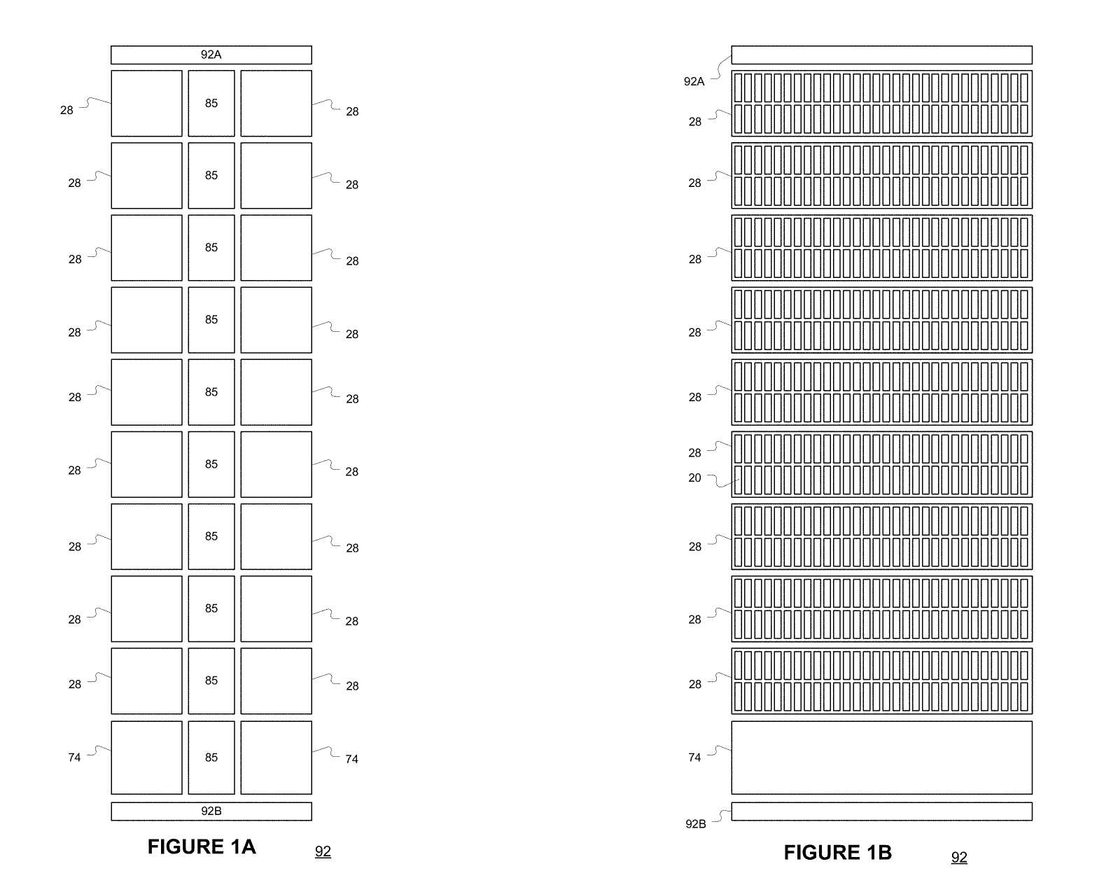

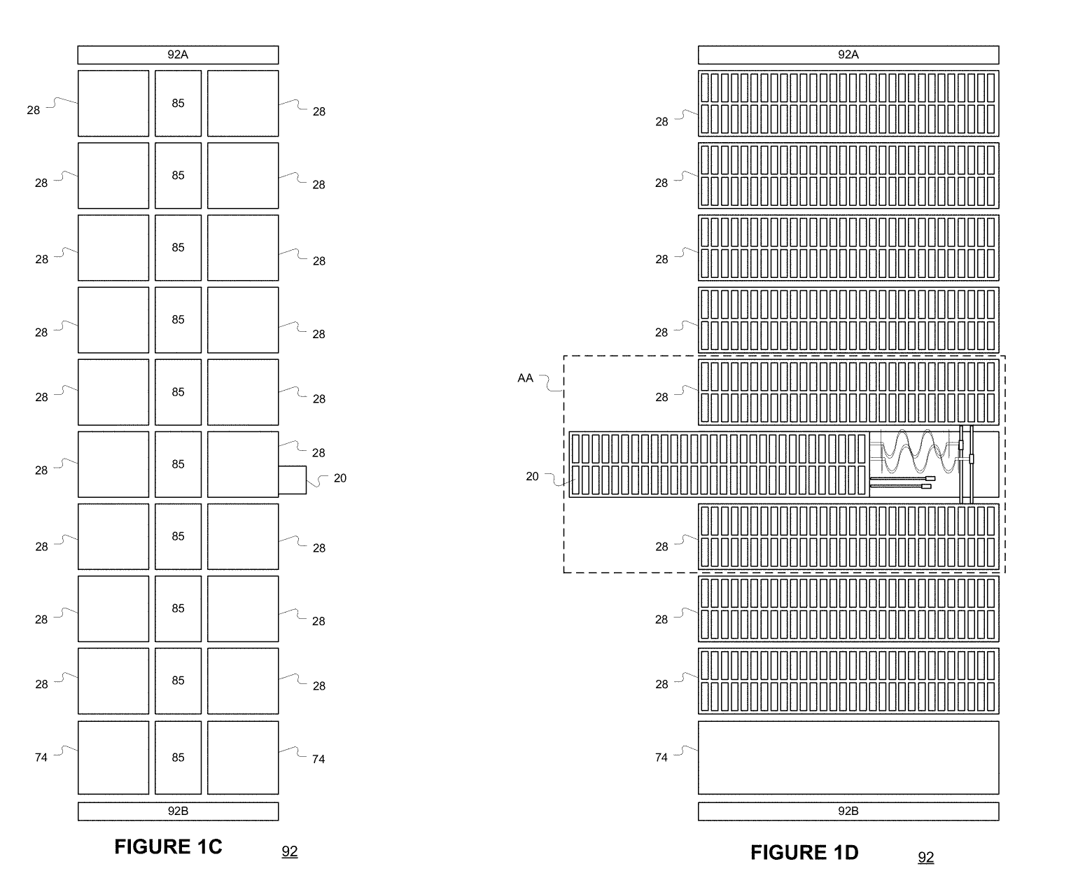

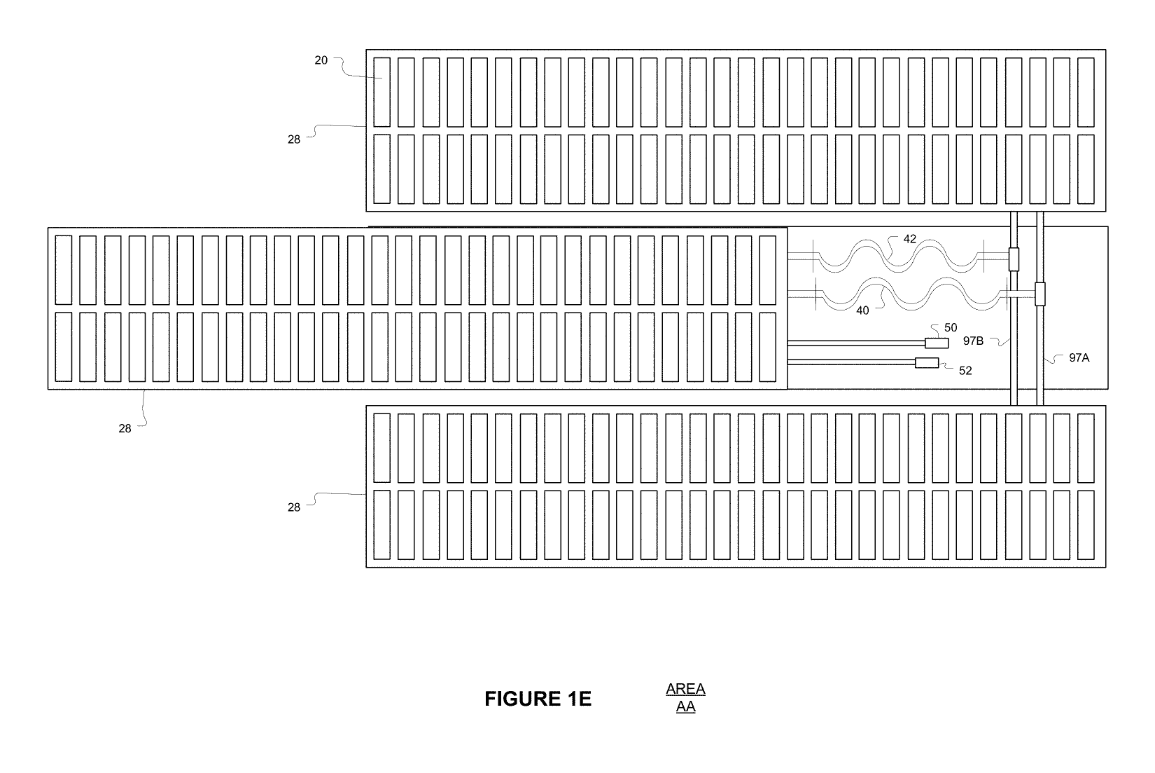

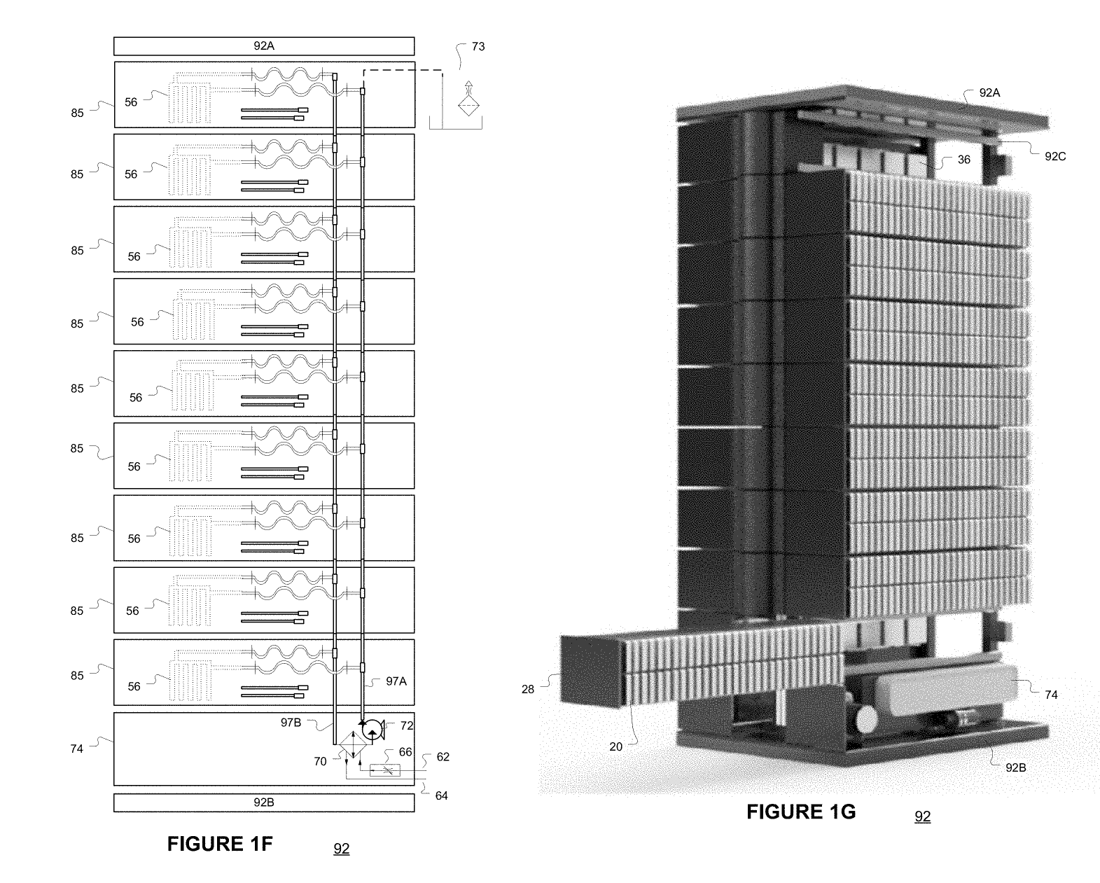

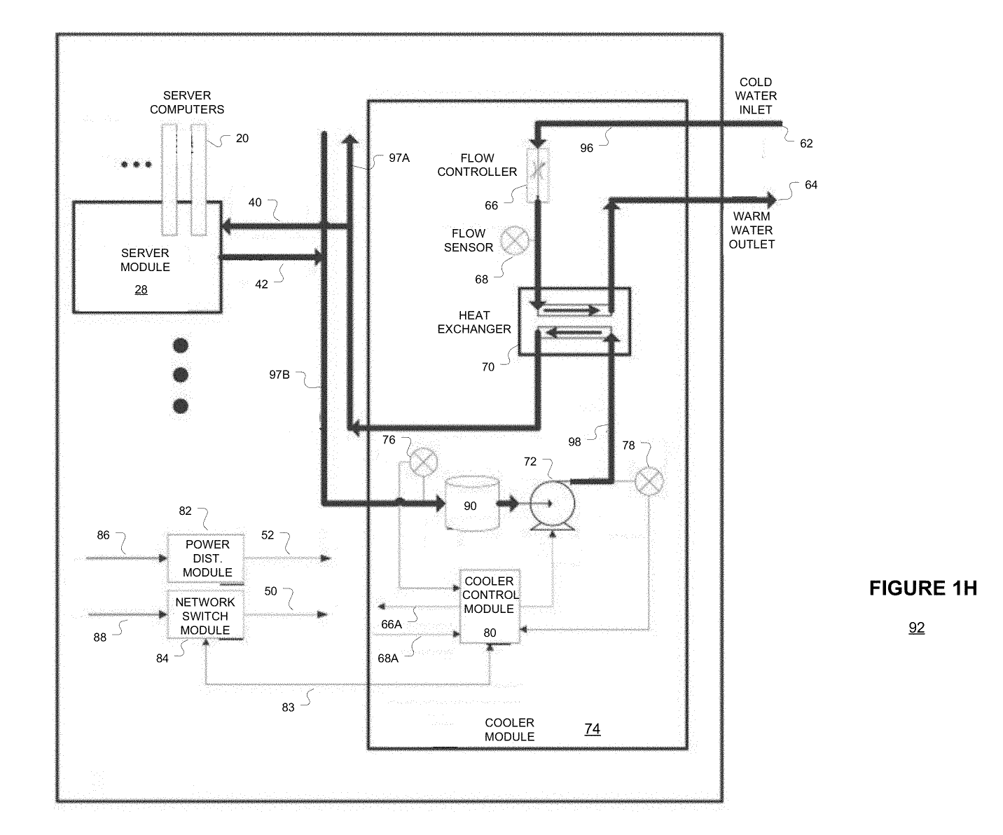

The present invention includes a multiple server architecture with server modules and cooler modules that enables cooling of the servers via liquid (for example, water) circuits, reducing costs and infrastructure (footprint and related cooling equipment) as shown in FIGS. 1A-1H. FIG. 1A is a simplified front diagram of a multiple server architecture (MSA) 92 with server modules 28, spacer modules 85, and cooler modules 74 according to various embodiments. FIG. 1B is a simplified side diagram of a multiple server architecture 92 with server modules 28, spacer modules 85, and cooler modules 74 according to various embodiments. FIG. 1C is a simplified front diagram of a multiple server architecture 92 with server modules 28, spacer modules 85, and cooler modules 74 with a server 20 partially seated in a server module 28 according to various embodiments. FIG. 1D is a simplified side diagram of a multiple server architecture 92 with server modules 28, spacer modules 85, and cooler modules 74 with a server module 28 partially slid forward to enable access to servers 20 according to various embodiments. FIG. 1G is an isometric image of a multiple server architecture 92 with server modules 28, spacer modules 85, and cooler modules with a server module 28 partially slid forward to enable access to servers 20 according to various embodiments.

As shown in FIGS. 1A-1D and 1G, MSA 92 may include a base or bottom 92A, top 92B, a plurality of server modules 28, a plurality of cooling modules 74, and a plurality of spacer modules 85 wherein a plurality of servers 20 may be seated into each server module 28. In an embodiment, MSA 92 may include 18 server modules (9 on each side), two cooling modules 74, and 10 spacer modules 85. In an embodiment, a server module 28 may seat or have slots for 60 servers 20, enabling MSA 92 to support 1,080 servers 20. In another embodiment, a MSA 192 may have 16 server modules 128 where each server module 128 may hold 20 servers 120.

In an embodiment such as MSA 192, no spacer modules 85 may exist between horizontally adjacent server modules 20 (120) and cooling modules 74 (174). In addition, the spacer modules 85 may be a single module or gap between horizontally adjacent server modules 20 and cooling modules 74 where the space may accommodate electrical and liquid conduits 97A, 97B, 50, and 52 shown in FIG. 1F.

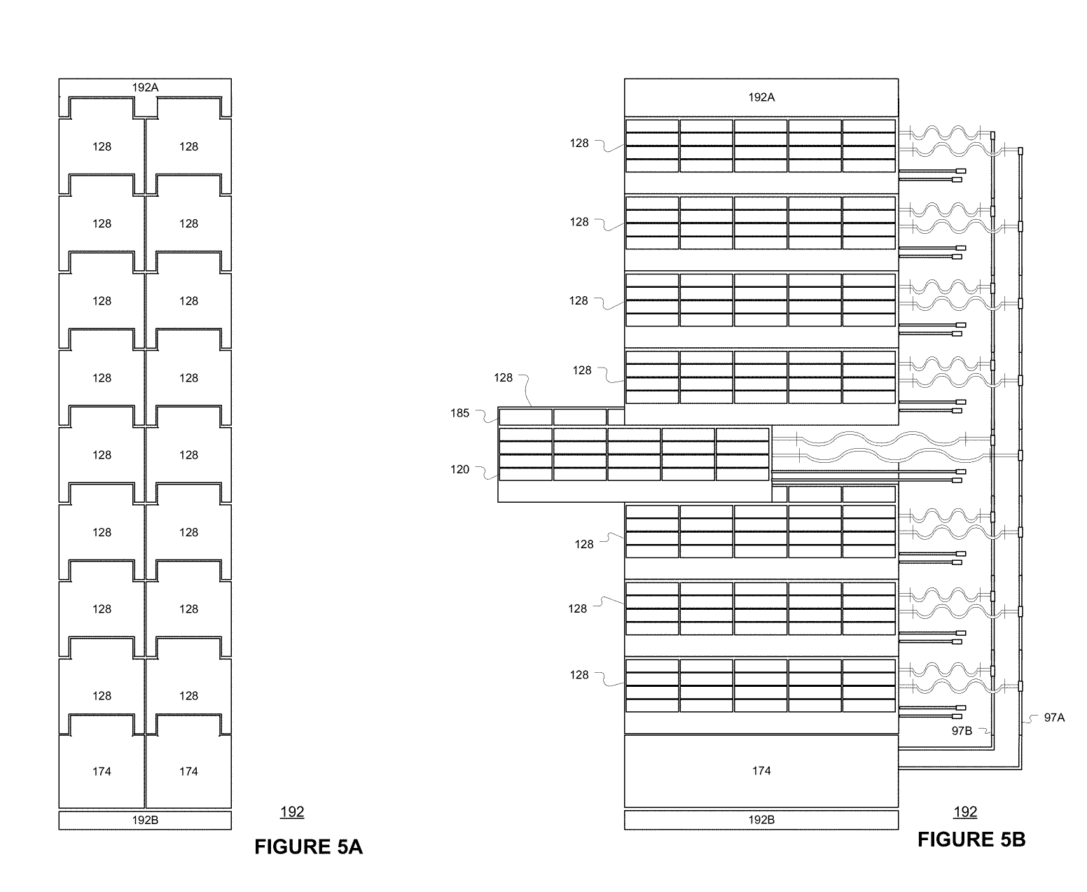

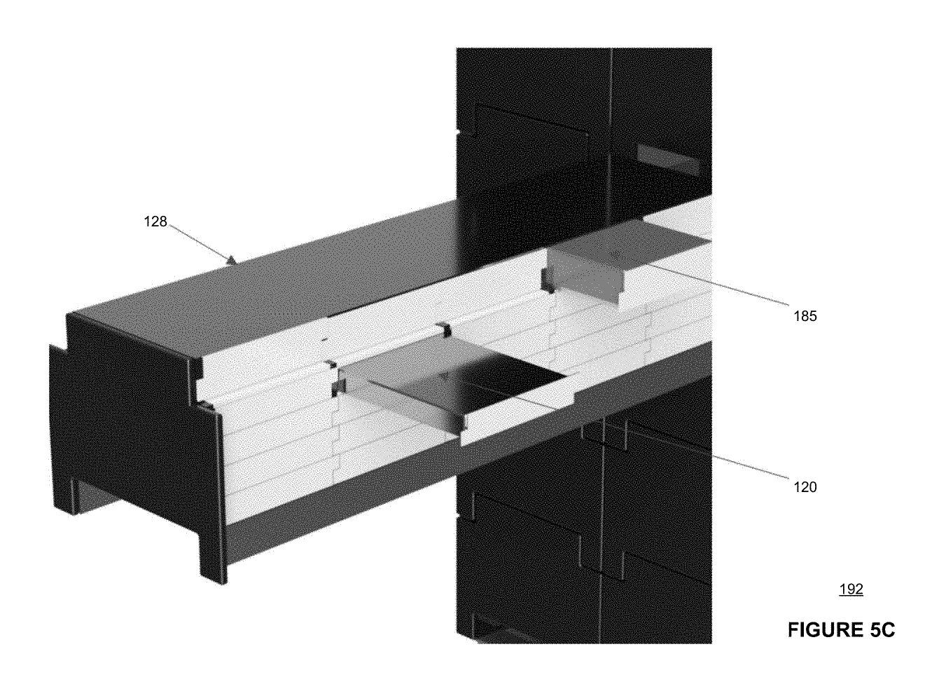

As shown in FIGS. 1A-1D, servers 20 may be inserted or seated into a server module 28 from the server module 28 and MSA 92 side vertically. As shown in FIGS. 5A-5C, in another embodiment, servers 120 may be inserted or seated into a server module 128 from the server module 128 and MSA 192 side horizontally. In addition, server modules 28 may slide from MSA 92 back to front to enable a server 20 to be removed or inserted into a slot 61 of a server module 28.

FIG. 1E is a simplified enlarged side diagram of area AA of multiple server architecture 92 shown in FIG. 1D according to various embodiments. FIG. 1F is a simplified side diagram of multiple server architecture 92 with spacer modules 85 and cooler modules 74 with server modules 28 removed from the right side to show underlying cooling connections 40, 42 and power and network connections 50, 52 according to various embodiments. As shown in FIGS. 1E and 1F, cooled liquid may be provided to a server module 28 via an inlet 40 and pipe 97A that extends to a cooling module 74. Warmed liquid may be provided from a server module 28 via a flexible pipe 42 and pipe 97B that extends to a cooling module 74. A spacer module 85 may provide network access via a network connection 50 and provide power via a power connection 52.

As shown in FIG. 1F, a cooling module 74 may include a flow controller 66, heat exchanger 70, and liquid pump 72. MSA 92 may include a vented reservoir 73. In an embodiment, chilled water (or other liquid) may be provided to a heat exchanger 70 via flow controller 66 from an MSA chilled liquid inlet 62 and warmed water (or other liquid) from the heat exchanger 70 may be passed to the MSA outlet 64. Chilled liquid may be pumped to all the server modules 28 via pipe 97A. Pipe 97A may also be coupled to a vented reservoir 73 to control regulate pressure in pipe 97A and reduce non-liquid present (remove air). As shown in FIG. 1F, inlet 40 may be coupled to a water circuit 56 that exists in the server modules 28.

The water circuits 56 may be coupled to the outlet 42 and pipe 97B that is coupled to the cooling module heat exchanger 70. In operation, as the liquid present in the closed loop formed by pipes 97A, 97B and inlet/outlets 40, 42, and liquid circuits 56 becomes heated, heat may be removed from the liquid via the heat exchanger 70 and captured by the liquid in the loop formed by inlet 62 and outlet 64. The flow regulator 66 regulate the flow rate of the liquid provided by the inlet 62 was a function of the temperature of liquid inside the loop formed by pipes 97A, 97B and inlet/outlet 40, 42, and liquid circuits 56. In an embodiment, the liquid in the 97A, 97B, inlet 40, outlet 42, circuits 56 may become gaseous and return to a liquid state in the heat exchanger 70.

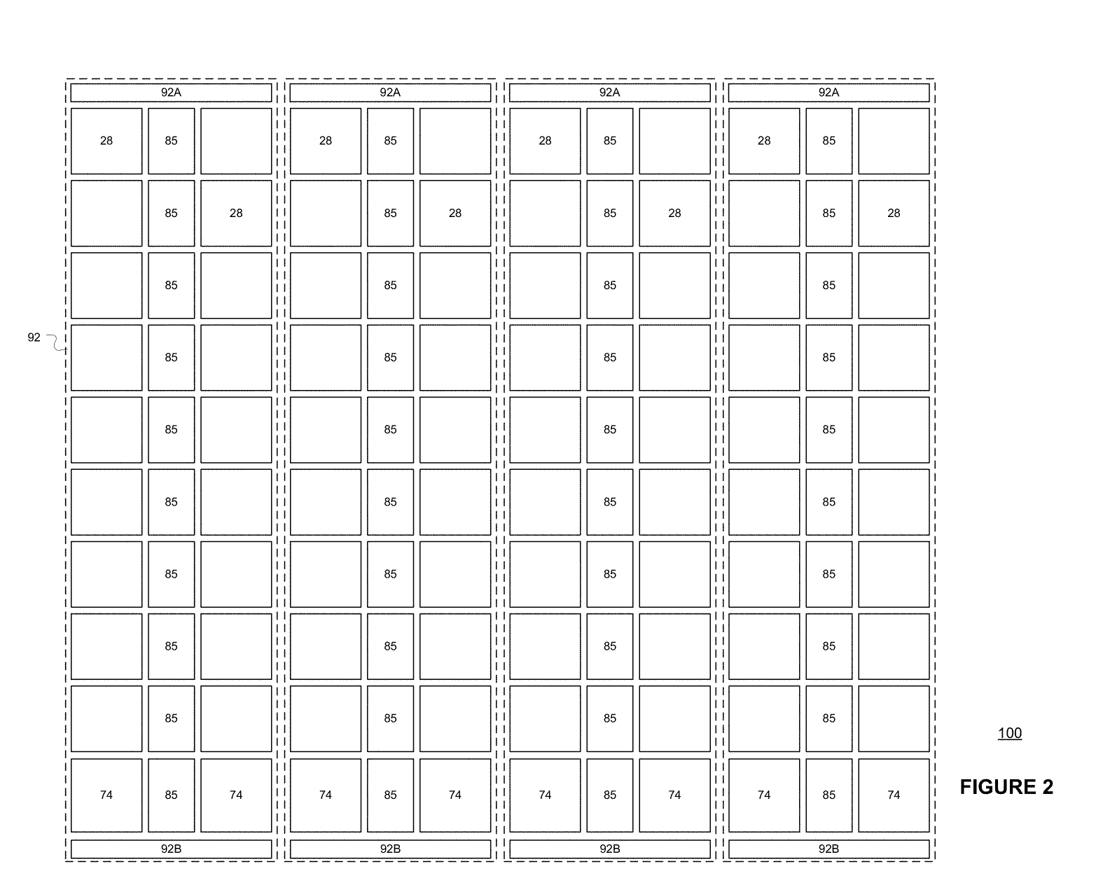

FIG. 2 is a simplified front diagram of a configuration 100 of a plurality of multiple server architectures 92 with server modules 28, spacer modules 85, and cooler modules 74 according to various embodiments. As shown in FIG. 2, a MSA 92 may be placed in close, adjacent proximity to other MSA 92. A User 112 may be able to remove a server 20 from a server module 28 by sliding the server module 28 forward (towards the MSA 92 front) to expose the desired server 20. Due to the flexible coupling of connections 50 and 52 to power distribution module 82 and network switch module 84 and liquid via inlet 40, outlet 42, the server module 28 may be slide forward and a server 20 removed without affecting the operation of other servers in the MSA 92 including other servers 20 in the respective server module 28.

As shown in FIGS. 1A-1H, an embodiment of the present invention employs liquid based cooling to servers 20 via data center facility chilled water (inlet 60), without need or reduced need for any air circulation cooling, saving valuable space and energy costs. In an embodiment, a liquid circuit (formed via piping 40, 42, liquid circuits 56, and heat exchanger 70) is formed within the server modules 28, cooler modules 74, and MSA 92 where the servers 70 are thermally coupled to the server modules 28 while completely isolated from the water circuit.

As shown in FIGS. 1A-1H, the liquid circulation via pipes 97A, 97B, inlet 40, outlet 42, liquid circuits 56, and heat exchanger 70 and related control modules in the server modules 28 and cooler modules 74 are replaceable while other servers in other server modules remain operational, due to redundancy in design. As shown in FIG. 1H, the cooler module 74 control module 80 may measure liquid flow (66) temperature (76), and pressure (78) parameters, control, and optimize liquid flow, automatically maintaining desired server 20 temperature due to varying computing loads in the servers 20, climate and weather in the data center 100, thereby further optimizing the energy consumption of the cooling infrastructure.

Moreover, the cooling module 74 controller module 80 may be accessible remotely via a network connection 83 for central monitoring, tracking, and management of the data center 100 energy consumptions as well as identification of faulty servers or cooling modules 74 in a MSA 92.

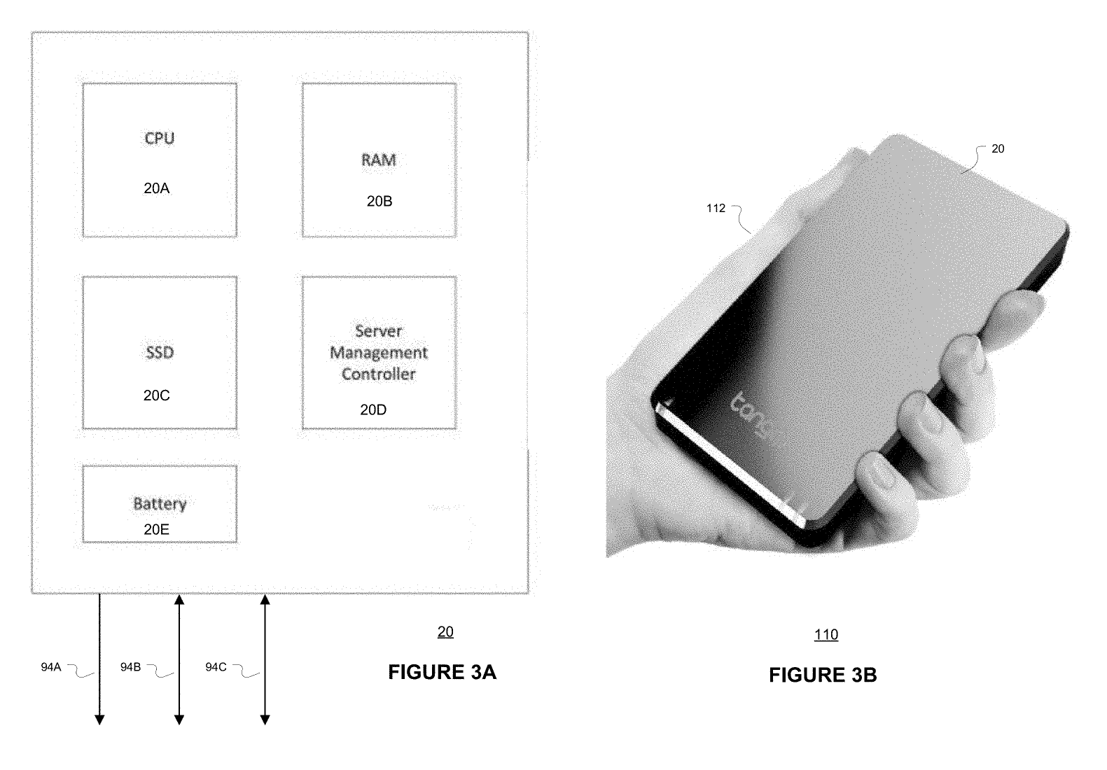

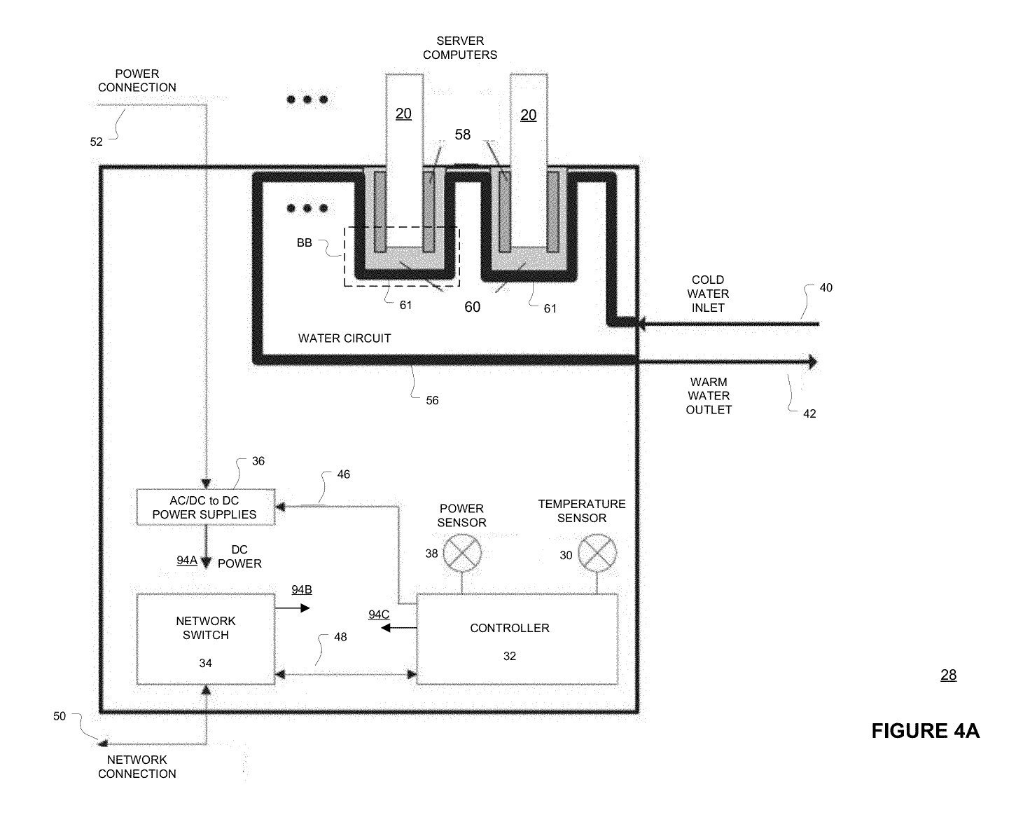

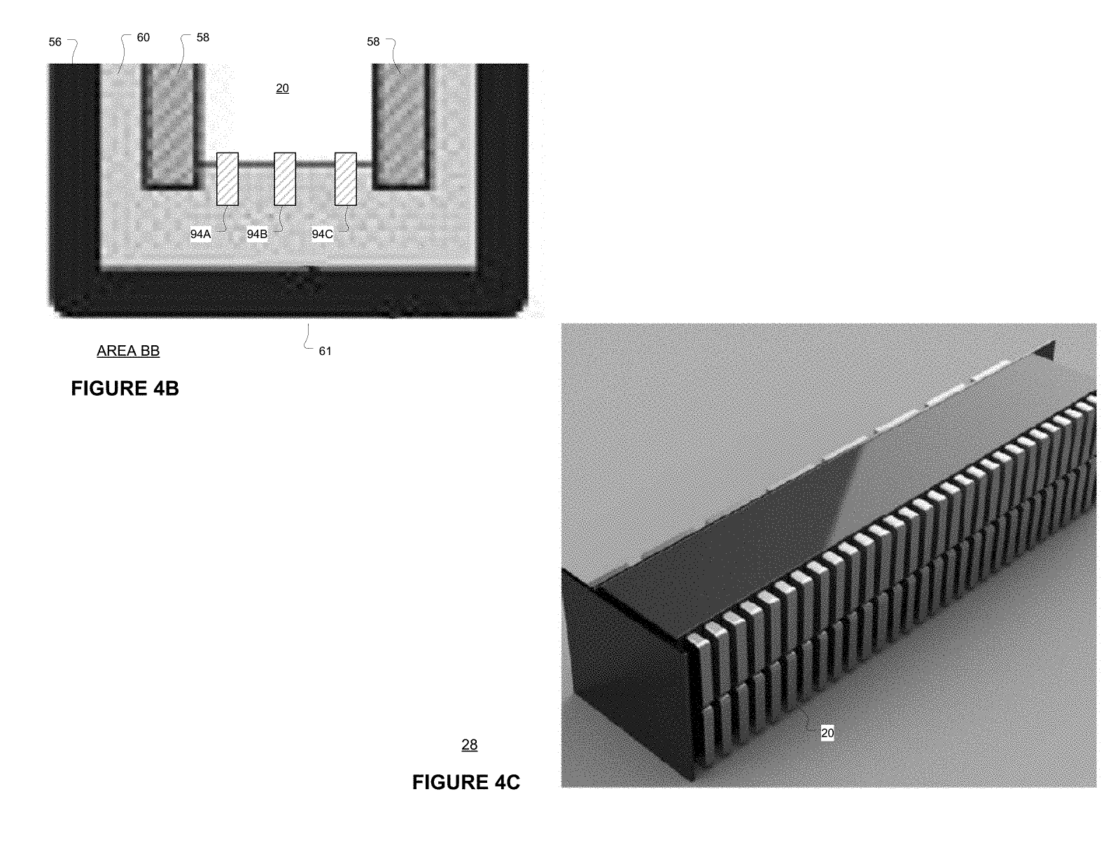

In an embodiment, the servers 20 are optimized for usage where the CPU 20A, RAM 20B, SSD 20C, and server management controller 20D (shown in FIG. 3A) may be coupled to a common heat conducting surface or two surfaces for engaging the two walls of a server module slot 61 (FIG. 4A). In addition, the servers 20 may receive DC power from a server module 28, reducing components needed to convert energy from AC or different DC voltage and the heat such components generate. Due to the density of servers 20 that the MSA 92 can support, the servers 20 may employ lower cost, lower energy usage, and lower temperature CPUs versus high speed, cutting edge CPUs, which typically require higher energy and generate substantial heat while operating at maximum operating speeds (sometimes overclocked generating excessive heat).

In data centers being employed to solve complex problems requiring high computing performance but serving a relatively to a small number of users, each server module 128 may host less, higher heat generating servers 120 such as shown in FIGS. 5A-5C. In data centers being employed to solve simple problems or surf the web, requiring low computing performance but serving a relatively to a large number of users, each server module 28 may host more, lower heat generating servers 20. In such data centers, it may be possible to reduce the server 20 hardware and heat dissipation costs significantly by employing a large number of small and economical commodity computers, compared to fewer high performance bulky and costly computers.

In such an embodiment, User 112 requests may be distributed to a large number of commodity computers depending on the task complexity. As shown in FIG. 3B, a server 20 according to an embodiment of the present invention may be compact and simple, termed a Nano Server. Each Nano server 20 is extremely compact and about the size of a typical cell phone, while still employing the same CPU, memory, and storage specifications of a commodity mainstream laptop computer. As noted, a MSA 92 may accommodate 1080 servers 20 compared to 42 servers currently accommodated in the same physical space, thus providing a potential significant boost in overall server rack 92 and significant reduction in the server hardware costs in addition to the direct liquid based cooling benefits.

In an embodiment, servers 20 may be thermally coupled to server module metal walls 60 via compliant thermally conductive material (fibers in an embodiment) 58 that may be deposited on the server module metal walls 60, on the servers 20 walls or both. Such a material 58 may include thermally conductive fibers as described in the incorporated related U.S. patent application Ser. No. 14/588,987 filed Jan. 5, 2015).

It is noted that server modules 28 employ a liquid circuit 56 that avoids leakage that may directly affect server 20 electronics operations by providing the liquid cooling mechanism within server modules 28, mechanically isolated and concealed within the server modules 28 with detachable connections (40, 42) that are away from server 20 electronics. It is further noted that the server modules 28 ensure that coupled servers 20 operating at safe temperature and that energy usage is minimized by providing an optional microprocessor 32 within the server module 28 to monitor the temperature 30 and control the power delivery to (36, 38), and monitor the performance of each coupled server 20.

In an embodiment, a server module 28 may include built-in network management electronics 34 including managed network switches so that an aggregate of three or less network connections 50 are needed to be coupled to a server module 28, while each server 20 docked to a server module 28 receives their own network connection. The module server 28 also enables a User 112 to easily modify the computing capacity within a MSA 92 since individual server modules 28 can be added to or removed from the MSA 92 by sliding them on or off the MSA 92, with pluggable electrical 52, network 50, and liquid connections 40, 42.

As shown in FIG. 1H, a cooler module in a MSA 92 may include a liquid pump 72 to circulate liquid to the server modules 28 in the MSA 92. The cooler module 74 may use pipes 97A, 97B within the MSA 92 to be coupled to multiple server modules 28 via inlets 40 and outlets 42, so individual server modules 28 do not need to be separately connected to a cooler module 74. As shown in FIGS. 1A-1H, a MSA 92 may include multiple cooler modules 74 to avoid cooling failure due to the failure of a single cooler module 74. As shown in FIGS. 1F and 1H, the cooling module 74 has isolated internal liquid flow from data center liquid flow via a heat exchanger 70.

In an embodiment, the cooler module 74 in conjunction with the server module 28 may ensure that the servers 20 coupled to a server module 28 within a MSA 92 receive desired cooling capability during computing loads within the servers 20. As shown in FIG. 1H, a cooling module 74 may include a microprocessor based control module 80 for measuring and monitoring of temperature, pressure, and flow of liquid in pipes 40, 42, and controlling a flow control valve 66 and water pump 72 accordingly. Due to the modular design of the MSA 92, the cooling capacity within the MSA 92 may be easily modified by adding or subtracting cooler modules 74 from the MSA 92 (by sliding them on or off the MSA 92 with pluggable electrical, network and liquid connections).

As shown in FIG. 2, multiple MSA 92 may be co-located without the need for aisles or server back side access given as maintenance access to liquid pipes, electric cables, and network cables along with all their pluggable joints of server modules 28, spacer modules 85, and cooler modules 74 may be accessed from the MSA 92 front. In another embodiment shown in FIGS. 5A-5C, the liquid and electrical conduits are located behind the server modules 128, requiring back side access to the MSA 192 reducing spacing between horizontally adjacent server modules 128 (no spacer modules 85).

The following definitions of terms are meant to clarify further an embodiment and functionality of some of the elements used in this application:

1. Server (computer) 20, 120: A device comprising of an electronic assembly comprising of a CPU 20A, RAM 20B, power management and network interface 20D. It may also additionally include storage memory 20C, microprocessor based server controller 20D, and batteries 20E. The server 20 may have a means to provide computing capability to a system it is connected to either wirelessly or through a wired interface.

2. Hot-swappable: Capability of a device to be able to mechanically and electrically attach or detach to a second device it functions with, without disrupting the functionality of the second device which may be in operation during the attachment or detachment. In some cases, it may be required to make the second device aware of the fact that the first device may be detached momentarily, or has already been attached.

3. Docking: An operation involving attaching an electronic device to a second device wherein the first device connects mechanically and electrically to the second device.

4. Thermally coupled docking: Docking of the first device to the second device, in which there exists a thermally conductive path from a body of the first device to a body of the second device.

5. Thermally conductive fiber pads: A proprietary thermal interface material generally having rectangular shape and thickness less than 1 mm, comprising thermally conductive fibers standing perpendicularly on a metal plate substrate surface secured through a suitable adhesive on the metal plate substrate. A detailed reference of a thermally conductive interface material is incorporated by reference to co-pending and commonly assigned U.S. patent application Ser. No. 14/588,987 filed on Jan. 5, 2015. Due to the conforming nature of the fiber, thermally conductive fiber pads provide a thermally conductive path between the two devices in a thermally coupled docking mechanism, when physically situated between the two devices.

6. Thermally dockable: A device designed to be capable of be thermally coupled to a system appropriately designed for such an operation. Thermally conductive fiber pads if used in the thermally coupling, may be optionally, and permanently attached either to the device, or to the system.

7. Flow sensor 68: A device capable of measuring and electronically relaying fluid flow information for the fluid flow through the vessel or pipe it is connected to.

8. Pressure sensor 78: A device capable of measuring and electronically relaying fluid pressure information for the fluid in the vessel or pipe it is connected to.

9. Temperature sensor 76: A device capable of measuring and electronically relaying temperature information of the body or the fluid in the vessel, or pipe it is connected to.

10. Power sensor 38: A device capable of measuring and electronically relaying the amount of electric power consumed by the system it is connected to.

11. Water pump 72: A device capable of moving a mass of fluid through a pipe or vessel it is connected to by applying pressure. Such a device can optionally be controlled electronically to vary the flow of mass or pressure.

12. Flow controller 66: A device capable of controlling the flow of fluid through itself either through a mechanical setting or through an electronic signal, or both. The device is connected to the system such that the fluid is expected to flow through the device itself while flowing through a part of the system.

13. Network switch 34: An assembly of electronic devices designed to primarily provide a network connectivity to a group of devices to a system it is connected to. Additional functionalities of a network switch comprise of management of network parameters remotely through the network itself, provide dynamic connection and disconnection of the devices within the group of devices and security. The network switch may have a combination of electrical and optical network interfaces.

14. Power distributor 82: An assembly of electro-mechanical devices designed to provide adequate power to multitude of equipment it is connected to, from a single or multitude of power sources. The power distributor may optionally have the capability to be operated through an electronic signal to control power delivered to the equipment it is connected to.

15. Power supply 36: An assembly of electro-mechanical devices designed to provide a desired voltage and current to the group of equipment it is connected to, from a power source. The power supply may optionally have the capability to be operated through an electronic signal to control the power delivered to the equipment it is connected to.

16. Heat exchanger 70: An equipment capable of exchanging heat between two separate fluid circulation systems without causing a mixture of the fluids themselves. The design principle of operation of the equipment is such that the amount of heat exchanged can be controlled within certain limits by varying the amount of individual fluid flow. The heat flows from higher temperature fluid to the lower temperature fluid, and in the process, the higher temperature fluid gets cooled and lower temperature fluid gets warmed.

17. Server 20: An embodiment of a server computer 20 that is portable and approaches the size so that it fits in a shirt pocket .Figures 3A-3B depicts a server 20 designed such that components of the electronic assembly it comprises of, that generate the majority of heat, are thermally coupled to its body.

Additionally, the server 20 provides a power 94A, network 94B, and server management interface 94C to the system it is designed to connect to, such that the system can communicate with the server 20 through the network interface 94B, deliver the power 94A to the server 20 and manage the state of the server 20 through the server management interface 94C. The system provides an input through the network interface 94B, on which the server, 20 performs computations and delivers the output result back to the system through network interface 94B. The server 20 is thermally dockable to a system which is appropriately designed for thermally coupled docking.

As noted, a MSA 92 may include a plurality of server modules 28. FIG. 4A is a partial block diagram of a server module 28 according to various embodiments. As shown in FIG. 4A, a server module 28 may include a network switch 34, AC/DC to DC power supplies 36, a controller 32, a power sensor 38, a temperature sensor 30, a water circuit 56, docking slots 61 including metal thermally conductive walls 60 and thermally conductive fiber pads 58. FIG. 4B is an enlarged diagram of area BB of a docking slot 61 shown in FIG. 4A according to various embodiments. FIG. 4C is an isometric image of a server module according to various embodiments. As shown in FIG. 4B, a server module docking slot 61 may include a thermally conductive pad 58 coupled to a metal wall 60, the metal wall adjacent to a liquid circuit 56. As also shown in FIG. 4B, the docking slot 61 may also include one or more electrical connections 94A, 94B, and 94C, where the connections may be a power connection 94A, a network connection 94B, and a server management interface connection 94C. In an embodiment, a single connection 94 may provide all functionality. As also shown in FIGS. 4A and 4B, the slots 61 provide two surfaces to contact and cool two sides of a server 20.

In an embodiment, a server module controller 32 may be the microprocessor based and provide the functionality comprising of power consumption, measurement, temperature measurement, power supply controlling, and management comprising of network, state and power of every server (computer) 20 docked to the server module 28. The server module may include a plurality of module power sensors 38 for measuring and relaying power consumption of server module 28 to the server module controller 32. It may also include a plurality of module temperature sensors 30 for measuring and relaying the temperature of the server module 28 to the server module controller 32. It may further include a module management interface 34 for managing the server module 28 remotely over a network connection.

As noted a plurality of hot-swappable, and portable server computers 20 may be thermally and electrically docked to a server module 28 for providing the MSA 92 computing capability. In an embodiment, a server module 28 includes a plurality of slots 61 (including module metal walls 60) for providing mechanical support, electrical and thermal coupling of docked server computers 20 to the server module 28, a plurality of thermally conductive and mechanically conforming module fiber pads 58 disposed on the metal walls 60 for providing mechanically detachable and conforming thermal coupling between a server computer 20 and a server module 28 at two sides. The server module 28 further includes a module fluid circuit 56 for liquid assisted cooling of server computers 20 and power supplies 36 by way of hollow features for liquid circulation concealed by the module's 38 slots 61 metal walls 60. The fluid circuit 56 may receive fluid or liquid from the pipe 97A and inlet 40 and communicate warm fluid to the pipe 97B via outlet 97B where the pipes 97A, 97B are coupled to the fluid circuit 56 via the inlet 40 and outlet 42 and the cooling module 74 heat exchanger 70.

A server module 28 may also include one or more hot-swappable module power supplies 36 disposed on and thermally coupled to the metal walls 60, with electrical output module DC power 94C which is electrically connected to the server module controller 32, network switch 34, and the plurality of server computers 20 docked to the server module 28 for providing power to the devices. In an embodiment, a power supply 36 may receive AC or DC power from a power distribution module 82 via the power connection 52 and convert the received power signal to the format and level required by the server 20 and other components 32, 34 of the server module 28. In an embodiment, the power supply 36 may receive a power control signal 46 from the controller 32 for controlling the power output and the state of the module power supplies 36 based on the electronic command signal from the server module controller 32.

FIG. 1H is a partial block diagram of a multiple server architecture (MSA) 92 with server modules 28, power distribution module 82, network switch module 84, and cooler modules 74 according to various embodiments. As shown in FIGS. 1A-1H, MSA 92 provides mechanical support, power distribution, network connectivity, cold and warm liquid supply plumbing. The MSA 92 may include sliding mechanisms or rails (92C, FIG. 1G) that enable hot-swappable server modules 28 and hot-swappable cooler modules 74 to be slidably coupled to the MSA 92. The cooler modules 74 may be remotely manageable and circulate liquid within the MSA 92 and the server modules 28. As shown in FIG. 1H, a cooling module 74 may include a microprocessor based cooler controller 80 for electronically measuring flow, pressure, and temperature of liquid in the system, and control of the fluid pump 72 (mentioned below), and flow controller 66 (mentioned below) so as to maintain the adequate liquid supply to server modules 28 within the required temperature range.

As also shown in FIG . 1H, the cooler module 74 may have a primary fluid circuit 96 that receives a MSA cold fluid inlet 62 for cold liquid inlet connection to an external cold liquid supply, a MSA warm fluid outlet 64 for warm liquid outlet connection to dispose warm liquid to an external system it is connected to. The cooler module 74 also includes a heat exchanger 70 for providing the functionality to cool internally circulated liquid within the server rack 92 with an externally supplied cold liquid from the MSA 92 cold fluid inlet 62 without mixing the liquid from the externally supplied liquid and liquid circulated in the MSA 92. The cooler module 74 may also include a flow controller 66 controlled by the cooler controller 80, for providing the functionality to electronically control the flow of the external liquid supply into the heat exchanger 70.

The cooler module 74 may also include a flow sensor 68 electrically connected to the controller 80 for providing the functionality to sense and relay the flow information of external water supply to the cooler controller 80. The cooler module 74 may also have a secondary fluid circuit 98 further including a fluid pump 72 electrically connected to the controller 80 for circulation of liquid within the cooler module 74 through the MSA 92 to each server module 28 and back to the cooler module 74 through the server rack 92 via pipes 97A, 97B. The cooler module 74 may also include a sealed fluid reservoir 90 for storing excess liquid and to provide adequate liquid circulation and a cooler temperature sensor 76 for measurement and relay of temperature to the cooler controller 80. The cooler module 74 may also include a cooler pressure sensor 78 for measurement and relay of water pressure at the outlet of the fluid pump 72 to the cooler controller 80.

The power distribution module 82 may receive power from a MSA power connection 86 and distribute power to server modules 28 and cooler modules 74 from the external power connection 86. The network switch module 84 may be coupled to a MSA network connection 88 and providing managed network connectivity for each server module 28 and each cooler module74 with the external network connection 88. In an embodiment, each server module 28 network switch 34 may be directly coupled to a data center 100 network port.

In an embodiment, the liquid assisted cooling mechanism within the server module 28 may work as follows:

1. Colder liquid may enter the server module 28 through the pipe 97A and cold fluid inlet 40 under pressure.

2. Due the pressure applied, the liquid circulates in the module fluid circuit 56.

3. Because the module power supplies 36 are thermally coupled to the module metal walls 60, which in turn are thermally coupled with the liquid in the module fluid circuit 56, heat from module power supplies 36 may flow into the liquid, resulting in cooling of the module power supplies 36 and warming of the liquid.

4. Because the thermally docked server computers 20 are thermally coupled to the thermally conductive and mechanically conforming fiber pads 58, which in turn are thermally coupled with module metal walls 60, which in turn is thermally coupled with the liquid in the module fluid circuit 56, heat from the server computers 20 may flow into the liquid, resulting in cooling of the server computers 20 and warming of the liquid.

5. The warmed liquid exits the server module 28 through the module warm fluid outlet or pipe 42.

In an embodiment, the module management 32 of a server module 28 may work as follows:

1. The microprocessor based server module controller 32 may receive remote commands from a remote management computer through the module management interface 48 of the network switch 34, receive temperature measurements from a plurality of module temperature sensors 30, receive network state information from the module network switch 34, and receive the power consumption measurements from a plurality of module power sensors 38.

2. The server module controller 32 may use the measurements and state information to compute and then output electronic signals including power control to control power output of plurality of power supplies 36, send commands to management interface 48 to instruct changes in network state of the module network switch 34, send commands to module management interface 48 to supply state information, and send commands to server management interface 94C to change the power and state of a plurality of server computers 20

It is of common knowledge in trade that liquid can be replaced by various other fluids for cooling purposes, including refrigeration fluids with suitable engineering modifications. Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

The accompanying drawings that form a part hereof show, by way of illustration and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein individually or collectively by the term “invention” merely for convenience and without intending to voluntarily limit the scope of this application to any single invention or inventive concept, if more than one is in fact disclosed. Thus, although specific embodiments have been illustrated and described herein, any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

For example, another MSA 192 as shown in FIGS. 5A-5C may include server modules 128 that include one or more power modules 136. FIG. 5A is a simplified front diagram of another multiple server architecture 192 with server modules 128 and cooler modules 174 according to various embodiments. FIG. 5B is a simplified side diagram of a multiple server architecture 192 shown in FIG. 5A with server modules 128 and cooler modules 174 with a server module 128 partially slid forward to enable access to servers 120 and power modules 185 according to various embodiments. FIG. 5C is an isometric image of a multiple server architecture 192 shown in FIG. 5A with server modules 128 and cooler modules 174 with a server module 128 partially slid forward to enable access to servers 120 and power modules 185 according to various embodiments.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In the foregoing Detailed Description, various features are grouped together in a single embodiment for the purpose of streamlining the disclosure. This method of disclosure is not to be interpreted to require more features than are expressly recited in each claim. Rather, inventive subject matter may be found in less than all features of a single disclosed embodiment. Thus the following claims are hereby incorporated into the Detailed Description, with each claim standing on its own as a separate embodiment.

What is claimed is:

1. A system for docking a plurality of portable computing devices, each computer device having a heat transmitting surface, the system including:
a front;
a back;
a dock for a multiple portable computer docking module
a dockable multiple portable computer docking module including:
a front;
a back;
a side;
a plurality of docking slots formed in the side, each slot sized to receive one of the plurality of portable computing devices;
wherein the multiple portable computer docking module is shaped so in operation with the system its front is parallel to the system front.

2. The system for docking a plurality of portable computing devices of claim 1, wherein the multiple portable computer docking module further includes a liquid circuit formed to traverse near each of the plurality of docking slots to adsorb heat from a portable computer device docked in each of the plurality of docking slots.

3. The system for docking a plurality of portable computing devices of claim 2, wherein each of the plurality of portable computer device includes an electrical connector to receive operational electrical power and each of the plurality of docking slots includes a complementary electrical connector to provide operational electrical power to a docked portable computer device.

4. The system for docking a plurality of portable computing devices of claim 3, wherein the multiple portable computer docking module further includes a power supply that provides operational electrical power to each of the plurality of docking slots.

5. The system for docking a plurality of portable computing devices of claim 4, wherein the multiple portable computer docking module further includes a liquid circuit formed to traverse near each of the plurality of docking slots to adsorb heat from a portable computer device docked in each of the plurality of docking slots and to traverse near the power supply to adsorb heat from a power supply.

6. The system for docking a plurality of portable computing devices of claim 1, wherein each of the plurality of docking slots includes a thermally conductive material that becomes thermally connected to a docked portable computer device.

7. The system for docking a plurality of portable computing devices of claim 6, wherein the multiple portable computer docking module further includes a liquid circuit formed to traverse near the thermally conductive material in each of the plurality of docking slots to adsorb heat from a portable computer device docked in each of the plurality of docking slots.

8. The system for docking a plurality of portable computing devices of claim 7, wherein the thermally conductive material includes thermal conducting fibers.

9. The system for docking a plurality of portable computing devices of claim 7, wherein each computer device of the plurality of portable computing devices has a heat transmitting surface and each of the plurality of docking slots includes a thermally conductive material that becomes thermally connected to the heat transmitting surface of docked portable computer device.

10. The system for docking a plurality of portable computing devices of claim 9, wherein the multiple portable computer docking module further includes a liquid circuit formed to traverse near the thermally conductive material in each of the plurality of docking slots to adsorb heat from the heat transmitting surface of a portable computer device docked in each of the plurality of docking slots.

11. The system for docking a plurality of portable computing devices of claim 10, wherein the thermally conductive material includes thermal conducting fibers.

12. The system for docking a plurality of portable computing devices of claim 10, wherein the multiple portable computer docking module further includes a power supply that provides operational electrical power to each of the plurality of docking slots.

13. The system for docking a plurality of portable computing devices of claim 12, wherein the multiple portable computer docking module further includes a liquid circuit formed to traverse near the thermally conductive material in each of the plurality of docking slots to adsorb heat from the heat transmitting surface of a portable computer device docked in each of the plurality of docking slots and to traverse near the power supply to adsorb heat from the power supply.

14. The system for docking a plurality of portable computing devices of claim 13, wherein the thermally conductive material includes thermal conducting fibers.

15. The system for docking a plurality of portable computing devices of claim 1, wherein each computer device of the plurality of portable computing devices has a top side heat transmitting surface and an opposite bottom side heat transmitting surface and each of the plurality of docking slots includes a first thermally conductive material that becomes thermally connected to the top side heat transmitting surface of docked portable computer device and a second thermally conductive material that becomes thermally connected to the bottom side heat transmitting surface of docked portable computer device.

16. The system for docking a plurality of portable computing devices of claim 15, wherein the multiple portable computer docking module further includes a liquid circuit formed to traverse near the first thermally conductive material and the second thermally conductive material in each of the plurality of docking slots to adsorb heat from the top and the bottom side heat transmitting surface of a portable computer device docked in each of the plurality of docking slots.

17. The system for docking a plurality of portable computing devices of claim 16, wherein the first thermally conductive material and the second thermally conductive material include thermal conducting fibers.

18. The system for docking a plurality of portable computing devices of claim 15, wherein the multiple portable computer docking module further includes a power supply that provides operational electrical power to each of the plurality of docking slots.

19. The system for docking a plurality of portable computing devices of claim 18, wherein the multiple portable computer docking module further includes a liquid circuit formed to traverse near the first thermally conductive material and the second thermally conductive material in each of the plurality of docking slots to adsorb heat from the top and the bottom side heat transmitting surface of a portable computer device docked in each of the plurality of docking slots and to traverse near the power supply to adsorb heat from the power supply.

20. The system for docking a plurality of portable computing devices of claim 19, wherein the first thermally conductive material and the second thermally conductive material include thermal conducting fibers.
